(19) United States
(12) Patent Application Publication
(10) Pub. No.: US 2026/0282635 A1
(43) Pub. Date: Sep. 17, 2026

(54) DISPLAY APPARATUS

(71) Applicant: SAMSUNG ELECTRONICS CO., LTD., Suwon-si (KR)

(72) Inventors: Taeyeon KIM, Suwon-si (KR); Hyesung HAN, Suwon-si (KR); Hyukjun JANG, Suwon-si (KR); Chunsoon PARK, Suwon-si (KR); Sujin KIM, Suwon-si (KR)

(73) Assignee: SAMSUNG ELECTRONICS CO., LTD., Suwon-si (KR)

(21) Appl. No.: 19/635,526

(22) Filed: Mar. 31, 2026

Related U.S. Application Data
(63) Continuation of application No. PCT/KR2026/001375, filed on Jan. 23, 2026.

(30) Foreign Application Priority Data
Mar. 13, 2025 (KR) 10-2025-0033025
May 26, 2025 (KR) 10-2025-0068595

(51) Int. Cl. H10H 29/49; H10H 29/24

(52) U.S. Cl. CPC H10H 29/49; H10H 29/24

(57) ABSTRACT

A display apparatus includes: a substrate; a plurality of light-emitting diodes (LEDs) arranged on the substrate in a two-dimensional matrix; a plurality of pixel integrated circuits (ICs) each configured to drive a defined number of LEDs; a plurality of LED lines configured to connect the defined number of LEDs and the pixel IC; a scan line configured to transmit and receive scan data between the plurality of pixel ICs; a power line configured to transmit and receive power between the plurality of pixel ICs; and a first multi-channel jumper at a first convergence region, wherein at least three lines among the one or more LED lines, the scan line, and the power line converge at the first convergence region; and wherein the first multi-channel jumper is configured to isolate the at least three lines from each other.

### CROSS-REFERENCE TO RELATED APPLICATION(S)

This application is a continuation of International Application No. PCT/KR 2026/001375, filed on Jan. 23, 2026, which claims priority to Korean Patent Application Nos. 10-2025-0033025 and 10-2025-0068595 filed, respectively, on Mar. 13, 2025 and May 26, 2025 in the Korean Intellectual Property Office, the disclosures of which are incorporated by reference herein in their entirety.

### BACKGROUND

The present disclosure relates to a display apparatus including a jumper element.

In general, a display apparatus converts acquired or stored electrical information into visual information to display the visual information for users. The display apparatus is widely used in various fields, such as at home or places of business.

The display apparatus may include a backlight unit (BLU) that provides light to a liquid crystal panel, and the backlight unit may include a plurality of point light-emitting devices that may independently emit light. The light-emitting devices may include, for example, light-emitting diodes (LEDs) or organic light-emitting diodes (OLEDs).

Such light-emitting devices may be driven by a pixel integrated circuit (IC), and a jumper element may be disposed in a region where wires for connecting the pixel IC and a plurality of light-emitting devices and other elements intersect to prevent the multiple wires from physically contacting each other.

### SUMMARY

One or more embodiments of the present disclosure may provide a display apparatus with a reduced number of jumper elements by rearranging a wiring structure on a single-sided printed circuit board (PCB).

Technical aspects that can be achieved by the present disclosure are not limited to the above-mentioned aspects, and other technical aspects not mentioned will be clearly understood by one of ordinary skill in the technical art to which the present disclosure belongs from the following description.

One or more embodiments of the present disclosure may provide display apparatus including: a substrate; light-emitting diodes (LEDs) on the substrate; a first pixel integrated circuit (IC) configured to drive one or more of the LEDs; one or more LED lines configured to connect the one or more of the LEDs to the first pixel IC; a scan line configured to transmit and receive scan data between the first pixel IC and one or more second pixel ICs; a power line configured to transmit and receive power between the first pixel IC and the one or more second pixel ICs; and a first multi-channel jumper at a first convergence region, wherein at least three lines among the one or more LED lines, the scan line, and the power line converge at the first convergence region; and wherein the first multi-channel jumper is configured to isolate the at least three lines from each other.

One or more embodiments of the present disclosure may provide display apparatus including: a substrate; light-emitting diodes (LEDs) on the substrate; a first pixel integrated circuit (IC) configured to drive one or more of the LEDs; one or more LED lines configured to connect the one or more of the LEDs to the first pixel IC; a scan line configured to transmit and receive scan data between the first pixel IC and a second pixel IC; a power line configured to transmit and receive power between the first pixel IC and the second pixel IC; and multi-channel jumpers respectively arranged adjacent to the first pixel IC at convergence regions, wherein the one or more LED lines, the scan line, and/or the power line converge at the convergence regions.

### BRIEF DESCRIPTION OF DRAWINGS

FIG. 1 illustrates an example of an appearance of a display apparatus according to one or more embodiments.

FIG. 2 illustrates an example of a configuration of a display apparatus according to one or more embodiments.

FIG. 3 illustrates an example of a liquid crystal panel included in a display apparatus according to one or more embodiments.

FIG. 4 illustrates an example of a backlight unit included in a display apparatus according to one or more embodiments.

FIG. 5 is a diagram illustrating that a plurality of light-emitting diodes (LEDs) of a backlight unit are divided into dimming blocks according to one or more embodiments.

FIG. 6 is a control block diagram of a display apparatus according to one or more embodiments.

FIG. 7 illustrates an example in which a display apparatus converts image data into dimming data according to one or more embodiments.

FIG. 8 illustrates an example of a light-emitting device included in a backlight unit according to one or more embodiments.

FIG. 9 illustrates another example of a light-emitting device included in a backlight unit according to one or more embodiments.

FIG. 10 is a diagram illustrating a structure of a pixel integrated circuit (IC) and LEDs according to one or more embodiments.

FIG. 11 is a diagram illustrating a pin structure of a pixel IC according to one or more embodiments.

FIG. 12 is a diagram illustrating an existing structure of a pixel IC and wiring and an arrangement of jumper elements.

FIG. 13 is a diagram illustrating a structure of a pixel IC and wiring and an arrangement of multi-channel jumpers according to one or more embodiments.

FIG. 14 is a diagram illustrating a distance between a plurality of LEDs according to one or more embodiments.

FIG. 15 is a diagram illustrating a structure of a pixel IC and wiring and an arrangement of multi-channel jumpers according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In addition, the terms “portion”, “part”, “unit”, “module” or “member” may be implemented in hardware or software. Depending on the embodiments, a plurality of “portions”, “parts”, “units”, “modules” or “members” may be implemented as a single element, or a single “portion”, “part”, “unit”, “module” or “member” may include a plurality of elements.

It will be understood that, although the terms “first”, “second”, “third”, “primary”, “secondary”, “tertiary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

When an element (e.g., a first element) is referred to as being “(functionally or communicatively) coupled” or “connected” to another element (e.g., a second element), the first element may be connected to the second element, directly (e.g., wired), wirelessly, or through a third element.

In this disclosure, the terms “containing”, “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

In addition, in the present disclosure, the meaning of “identical” includes cases where properties are similar to each other or similar within a certain range. Furthermore, unless clearly indicated, stated, and/or shown otherwise; as used herein the terms “identical”, “uniform”, “equal”, and/or “the same” mean “substantially identical”, “substantially uniform”, “substantially equal”, “about the same”, and/or “substantially the same”. The meaning of substantially identical should be understood to include numerical values within manufacturing error ranges, machining or processing tolerances, and/or differences within a range that is so insignificant such that neither the structure nor function of the embodiments disclosed herein are materially altered, inhibited, or destroyed.

Unless otherwise indicated, as used herein with regard to any plurality of a particular type of component, any two components of that type are considered “adjacent” or “adjacent to” one another so long as no other component of that type occupies a space between the two components. That is, the two components are considered adjacent each other if the two components are not separated from each other by an intervening component of that type.

Furthermore, although one or more embodiments may comprise the disclosed features as described herein—as well as additional features not specifically described—other embodiments may instead be completely free of non-disclosed elements. For example, non-disclosed elements may be completely omitted from one or more embodiments of the present disclosure.

As used herein, the terms “front (or forward)”, “rear (or back, backward, rearward)”, “up (or upper, top, above)”, “down (or lower, bottom, below)”, “left”, “right”, and the like may be defined with reference to the drawings, and may not be intended to limit the shape and/or position of each component.

Hereinafter, embodiments of the present disclosure will be described in detail with reference to the accompanying drawings.

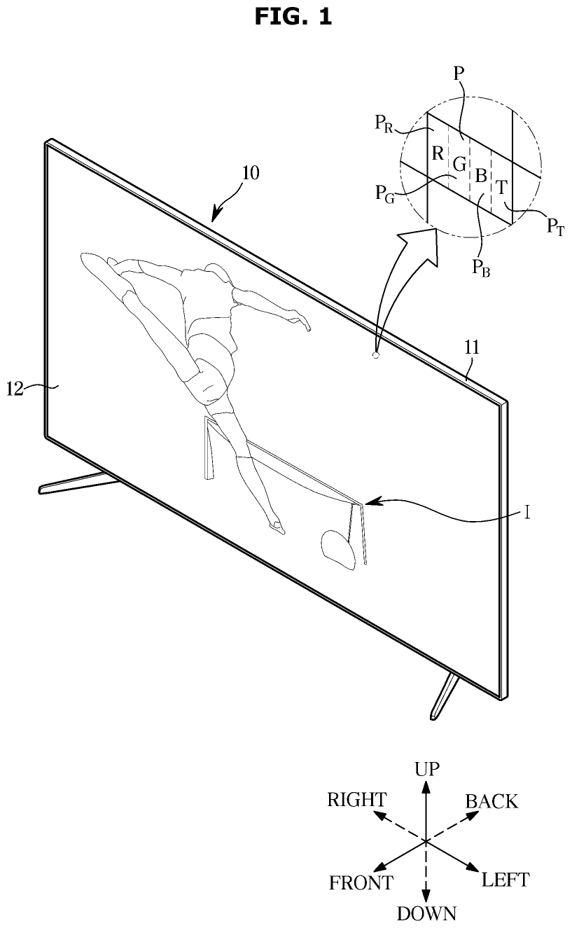

FIG. 1 illustrates an example of an appearance of a display apparatus according to an embodiment.

Referring to FIG. 1, a display apparatus 10 is a device capable of processing an image signal received from the outside and visually displaying a processed image. Hereinafter, a case in which the display apparatus 10 is a television (TV) is exemplified, but is not limited thereto. For example, the display apparatus 10 may be implemented in various forms, such as a monitor, a portable multimedia device, a portable communication device, and the like, and the form of the display apparatus 10 is not limited as long as it is a device that visually displays an image.

In addition, the display apparatus 10 may be a large format display (LFD) installed outdoors, such as a building rooftop or a bus stop. Here, the outdoors is not necessarily limited to an outdoor space, and the display apparatus 10 according to an embodiment may be installed wherever a large number of people may come and go, even indoors such as at subway stations, shopping malls, movie theaters, office buildings, and stores.

The display apparatus 10 may receive content including a video signal and an audio signal from various content sources, and output video and audio corresponding to the video signal and the audio signal, respectively. For example, the display apparatus 10 may receive content data through a broadcast reception antenna or a wired cable, receive content data from a content play back apparatus, or receive content data from a content-providing server of a content provider.

As shown in FIG. 1, the display apparatus 10 may include a main body 11 and a screen 12 for displaying an image I.

The main body 11 forms an exterior of the display apparatus 10, and components for the display apparatus 10 to display the image I or perform various functions may be provided inside the main body 11. The main body 11 shown in FIG. 1 has a flat plate shape, but the shape of the main body 11 is not limited to that shown in FIG. 1. For example, the main body 11 may have a curved plate shape.

The screen 12 is formed on a front surface of the main body 11, and may display the image I. For example, the screen 12 may display a still image or a video. In addition, the screen 12 may display a two-dimensional plane image or a three-dimensional stereoscopic image using binocular parallax of a user.

The screen 12 may include a liquid crystal panel capable of transmitting or blocking light emitted by a backlight unit (BLU), or the like.

A plurality of pixels P may be formed on the screen 12, and the image I displayed on the screen 12 may be formed by light emitted from each of the plurality of pixels P. For example, the image I may be formed on the screen 12 by combining light emitted from each of the plurality of pixels P like a mosaic.

Each of the plurality of pixels P may emit light of various brightness and various colors. In order to emit light of various colors, each of the plurality of pixels P may include sub-pixels PR, PG, PB, and PT.

The sub-pixels PR, PG, PB, and PT may include a red sub-pixel PR capable of selectively emitting red light, a green sub-pixel PG capable of selectively emitting green light, a blue sub-pixel PB capable of selectively emitting blue light, and a transparent sub-pixel PT capable of selectively emitting red light, blue light, and green light. For example, the red light may represent light having a wavelength of approximately 700 nm (nanometer, one billionth of a meter) to 800 nm. The green light may represent light having a wavelength of approximately 500 nm to 600 nm. The blue light may represent light having a wavelength of approximately 400 nm to 500 nm.

By combining the red light of the red sub-pixel PR, the green light of the green sub-pixel PG, the blue light of the blue sub-pixel PB, and the monochromatic light or mixed light of the transparent sub-pixel PT, light of various brightness and various colors may be emitted from each of the plurality of pixels P.

In the present disclosure, mixed light may refer to light in which at least two of red light, green light, and blue light are mixed, and monochromatic light may refer to each of red light, green light, and blue light.

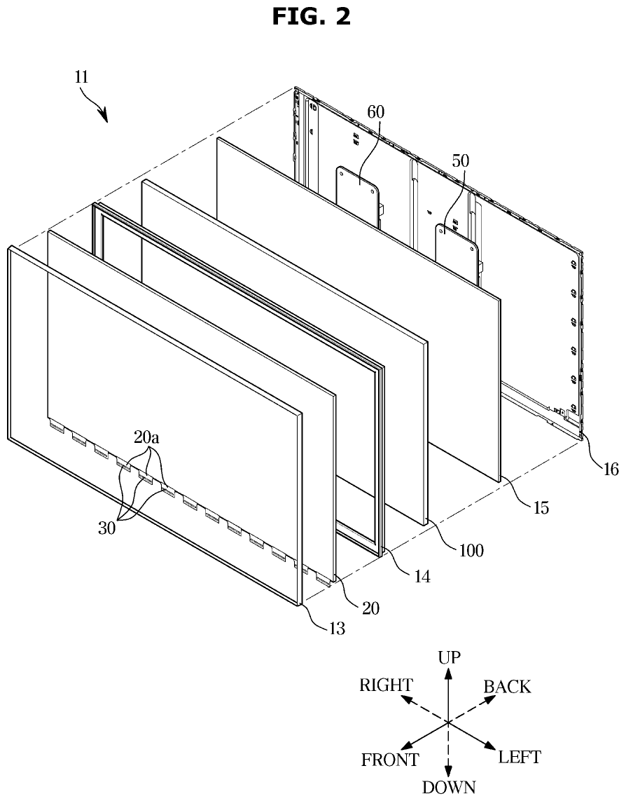

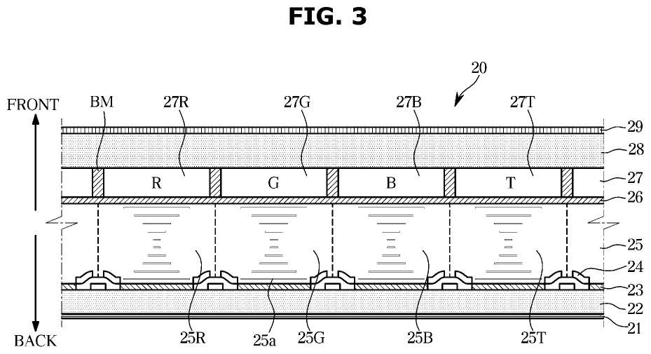

FIG. 2 illustrates an example of a configuration of a display apparatus according to an embodiment, and FIG. 3 illustrates an example of a liquid crystal panel included in a display apparatus according to an embodiment.

As shown in FIG. 2, various components for generating an image I on the screen 12 may be provided in the main body 11.

For example, the main body 11 may include a backlight unit 100 which is a surface light source, a liquid crystal panel 20 blocking or transmitting light emitted from the backlight unit 100, a control assembly 50 controlling operations of the backlight unit 100 and the liquid crystal panel 20, and a power assembly 60 supplying power to the backlight unit 100 and the liquid crystal panel 20. In addition, the main body 11 may include a bezel 13, a frame middle mold 14, a bottom chassis 15, and a rear cover 16 for supporting the liquid crystal panel 20, the backlight unit 100, the control assembly 50, and the power assembly 60.

The backlight unit 100 may include a point light source that emits mixed light (or white light). In addition, the backlight unit 100 may refract, reflect, and scatter the light to convert the light emitted from the point light source into a uniform surface light. As described above, the backlight unit 100 may refract, reflect, and scatter the light emitted from the point light source to emit a uniform surface light in a forward direction.

The backlight unit 100 may also be referred to as the light source apparatus 100 in that backlight unit 100 is a component for outputting light.

The backlight unit 100 will be described in more detail below.

The liquid crystal panel 20 is provided in front of the backlight unit 100, and blocks or transmits light emitted from the backlight unit 100 to form the image I.

A front surface of the liquid crystal panel 20 forms the screen 12 of the display apparatus 10 described above, and the liquid crystal panel 20 may form the plurality of pixels P. The plurality of pixels P of the liquid crystal panel 20 may independently block or transmit the light of the backlight unit 100. In addition, the light transmitted by the plurality of pixels P may form the image I to be displayed on the screen 12.

For example, as shown in FIG. 3, the liquid crystal panel 20 may include a first polarizing film 21, a first transparent substrate 22, a pixel electrode 23, a thin film transistor 24, a liquid crystal layer 25, a common electrode 26, a color filter 27, a second transparent substrate 28, and a second polarizing film 29.

The color filter 27 may be provided on the second transparent substrate 28. For example, the color filter 27 may be provided on the front surface of the second transparent substrate 28 or on the rear surface of the second transparent substrate 28.

A layer formed by arranging the color filter 27 on the second transparent substrate 28 may be referred to as color filter layers 27 and 28.

The first transparent substrate 22 and the second transparent substrate 28 may fixedly support the pixel electrode 23, the thin film transistor 24, the liquid crystal layer 25, the common electrode 26, and the color filter 27. The first transparent substrate 22 and the second transparent substrate 28 may be formed of tempered glass or transparent resin. For example, the first transparent substrate 22 and the second transparent substrate 28 may be referred to as a glass substrate.

The first polarizing film 21 and the second polarizing film 29 are provided on outer sides of the first transparent substrate 22 and the second transparent substrate 28. The first polarizing film 21 and the second polarizing film 29 may each transmit specific polarized light and block (reflect or absorb) the other polarized light. For example, the first polarizing film 21 may transmit light polarized in a first direction and block (reflect or absorb) the other polarized light. In addition, the second polarizing film 29 may transmit light polarized in a second direction and block (reflect or absorb) the other polarized light. In this instance, the first direction and the second direction may be orthogonal to each other. Thus, the polarized light passing through the first polarizing film 21 may not directly pass through the second polarizing film 29.

The color filter 27 may include, for example, a red filter 27R transmitting red light, a green filter 27G transmitting green light, and a blue filter 27B transmitting blue light.

The color filter 27 may be an absorption filter that transmits a specific wavelength band of incident light and absorbs the remaining wavelength band.

For example, the red filter 27R may transmit light in the wavelength band from 700 nm to 800 nm and absorb light in the remaining wavelength band.

The green filter 27G may transmit light in the wavelength band from 500 nm to 600 nm and absorb light in the remaining wavelength band.

The blue filter 27B may transmit light in the wavelength band from 400 nm to 500 nm and absorb light in the remaining wavelength band.

The color filter 27 may be distinguished from quantum dots that absorb incident light and then emit light of a specific wavelength. Accordingly, the color filter layers 27 and 28 are different from the quantum dot sheet.

In an embodiment, the color filter layers 27 and 28 include the red filter 27R, the green filter 27G, and the blue filter 27B disposed on the second transparent substrate 28, and may include a transparent region 27T on the second transparent substrate 28 where the red filter 27R, the green filter 27G, and the blue filter 27B are not formed.

The transparent region 27T may refer to a region on the second transparent substrate 28 where the red filter 27R, the green filter 27G, and the blue filter 27B are not formed.

According to various embodiments, a light diffusion member may be disposed on the transparent region 27T.

In the present disclosure, the transparent region 27T may be referred to as the transparent filter 27T in that the transparent region 27T transmits all incident light.

In an embodiment, the red filter 27R, the green filter 27G, the blue filter 27B, and the transparent filter 27T may be partitioned by a black matrix BM.

According to an embodiment of the present disclosure, the color filter layers 27 and 28 include the transparent filter 27T, thereby improving light efficiency.

The red filter 27R, the green filter 27G, the blue filter 27B, and the transparent filter 27T may be arranged side by side. The arrangement order of the red filter 27R, the green filter 27G, the blue filter 27B, and the transparent filter 27T may vary.

A region occupied by the color filter 27 and the transparent filter 27T corresponds to the pixel P described above. A region occupied by the red filter 27R corresponds to the red sub-pixel PR, a region occupied by the green filter 27G corresponds to the green sub-pixel PG, a region occupied by the blue filter 27B corresponds to the blue sub-pixel PB, and a region occupied by the transparent filter 27T corresponds to the transparent sub-pixel PT.

The black matrix BM may define boundaries between each sub-pixel PR, PG, PB, and PT. The width of each sub-pixel PR, PG, PB, and PT may correspond to the width of each cell of the black matrix BM.

The red sub-pixel PR, the green sub-pixel PG, the blue sub-pixel PB, and the transparent sub-pixel PT may form a single pixel P.

The liquid crystal panel 20 may include a plurality of pixels P each including the red sub-pixel PR, the green sub-pixel PG, the blue sub-pixel PB, and the transparent sub-pixel PT.

Each of the red sub-pixel PR, the green sub-pixel PG, the blue sub-pixel PB, and the transparent sub-pixel PT may be independently controlled.

The pixel electrode 23 may be provided on an inner side of the first transparent substrate 22, and the common electrode 26 may be provided on the inner side of the second transparent substrate 28. The pixel electrode 23 and the common electrode 26 are formed of a metal material through which electricity is conducted, and may generate an electric field for changing the arrangement of liquid crystal molecules 115a constituting the liquid crystal layer 25 to be described below.

The thin film transistor (TFT) 24 is provided on the inner side of the transparent substrates 22 and 28. The TFT 24 may be turned on (closed) or off (opened) by image data provided from a panel driver 30. In addition, by turning the TFT 24 on (closing) or off (opening), an electric field may be formed or removed from between the pixel electrode 23 and the common electrode 26.

The liquid crystal layer 25 is formed between the pixel electrode 23 and the common electrode 26, and is filled with liquid crystal molecules 25a. The liquid crystal may represent an intermediate state between a solid (crystal) and a liquid. The liquid crystal may exhibit optical properties depending on a change in electric field. For example, a direction of the molecular arrangement constituting the liquid crystal may change depending on a change in electric field. As a result, optical properties of the liquid crystal layer 25 may change according to the presence or absence of the electric field passing through the liquid crystal layer 25. For example, the liquid crystal layer 25 may rotate a polarization direction of light about an optical axis according to the presence or absence of the electric field. Accordingly, the polarized light that has passed through the first polarizing film 21 is changed in polarization direction while passing through the liquid crystal layer 25, and may pass through the second polarizing film 29.

The liquid crystal layer 25 may include a plurality of independently controllable liquid crystal cells. Each of the plurality of liquid crystal cells may be independently controlled by the TFT 24.

In the present disclosure, a liquid crystal cell may refer to a portion of the liquid crystal layer 25 that is independently controllable by the TFT 24.

Each of the plurality of liquid crystal cells may be aligned with the red filter 27R, the green filter 27G, the blue filter 27B, and the transparent filter 27T.

For example, the plurality of liquid crystal cells may include a first liquid crystal cell 25R aligned with the red filter 27R, a second liquid crystal cell 25G aligned with the green filter 27G, a third liquid crystal cell 25B aligned with the blue filter 27B, and a fourth liquid crystal cell 25T aligned with the transparent filter 27T.

Each of the plurality of liquid crystal cells 25R, 25G, 25B, and 25T may be controlled by a corresponding TFT 24.

The red sub-pixel PR may be formed by aligning the red filter 27R and the first liquid crystal cell 25R, the green sub-pixel PG may be formed by aligning the green filter 27G and the second liquid crystal cell 25G, the blue sub-pixel PB may be formed by aligning the blue filter 27B and the third liquid crystal cell 25B, and the transparent sub-pixel PT may be formed by aligning the transparent filter 27T and the fourth liquid crystal cell 25T.

An opening degree of each of the red sub-pixel PR, the green sub-pixel PG, the blue sub-pixel PB, and the transparent sub-pixel PT may be independently controlled depending on whether the corresponding TFT 24 is turned on (closed) or turned off (open).

At one edge of the liquid crystal panel 20, a cable 20a through which image data is transmitted to the liquid crystal panel 20 and a display driver integrated circuit (DDI) 30 (hereinafter, referred to as the “panel driver”) that processes digital image data and outputs an analog image signal may be provided.

The cable 20a may electrically connect between the control assembly 50/the power assembly 60 and the panel driver 30, and may also electrically connect the panel driver 30 and the liquid crystal panel 20. The cable 20a may include a flexible flat cable or a film cable that may be bendable.

The panel driver 30 may receive image data and power from the control assembly 50/the power assembly 60 through the cable 20a. Further, the panel driver 30 may provide image data and driving current to the liquid crystal panel 20 through the cable 20a.

In addition, the cable 20a and the panel driver 30 may be integrally implemented as a film cable, a chip on film (COF), a tape carrier packet (TCP), or the like. In other words, the panel driver 30 may be disposed on the cable 20a. However, the present disclosure is not limited thereto, and the panel driver 30 may be disposed on the liquid crystal panel 20.

The control assembly 50 may include a control circuit that controls operations of the liquid crystal panel 20 and the backlight unit 100. For example, the control circuit may process a video signal and/or an audio signal received from an external content source. The control circuit may transmit the image data to the liquid crystal panel 20, and may transmit dimming data to the backlight unit 100.

The power assembly 60 may include a power circuit supplying power to the liquid crystal panel 20 and the backlight unit 100. The power circuit may supply power to the control assembly 50, the backlight unit 100, and the liquid crystal panel 20.

The control assembly 50 and the power assembly 60 may be implemented with a printed circuit board and various circuits mounted on the printed circuit board. For example, the power circuit may include a condenser, a coil, a resistance element, a processor, and the like and a power circuit board on which these elements are mounted. In addition, the control circuit may include a memory, a processor, and a control circuit board on which these elements are mounted.

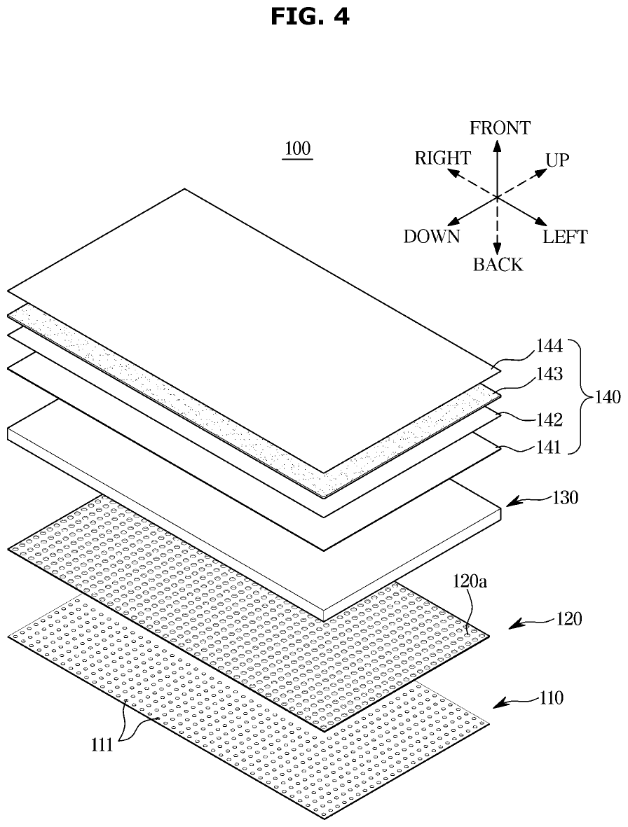

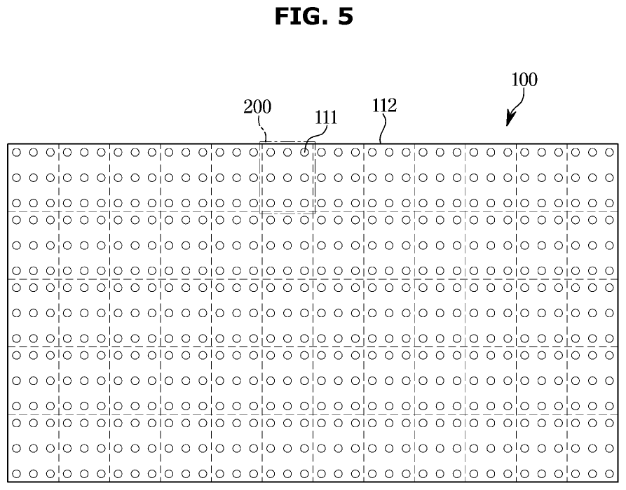

FIG. 4 illustrates an example of the backlight unit 100 included in the display apparatus 10, and FIG. 5 is a diagram illustrating that a plurality of LEDs of the backlight unit 100 are divided into dimming blocks according to an embodiment.

As shown in FIG. 4, the backlight unit 100 may include a light source module 110 generating light, a reflector sheet 120 reflecting light, a diffuser plate 130 uniformly diffusing light, and an optical sheet 140 improving luminance of the output light.

The light source module 110 may include a plurality of light-emitting devices 111 emitting light, and a substrate 112 supporting/fixing the plurality of light-emitting devices 111.

The plurality of light-emitting devices 111 may be arranged in a predetermined pattern to allow light to be emitted with uniform luminance. The plurality of light-emitting devices 111 may be arranged to allow a distance between a single light source and each light source adjacent thereto to be the same.

For example, as shown in FIG. 4, the plurality of light-emitting devices 111 may be aligned in rows and columns. For example, the plurality of light sources may be arranged to form an approximate square by four adjacent light sources. In addition, any one light source is disposed adjacent to four light sources, and a distance between the single light source and each of the four light sources adjacent to the single light source may be substantially the same.

Furthermore, according to embodiments, the plurality of light sources may be arranged such that three adjacent light sources form a substantially equilateral triangle. In this case, a single light source may be disposed adjacent to six light sources. In addition, a distance between the single light source and each of the six adjacent light sources may be substantially the same.

However, the arrangement of the plurality of light-emitting devices 111 is not limited to the arrangement described above, and the plurality of light-emitting devices 111 may be disposed in various patterns to allow light to be emitted with uniform luminance.

Each light-emitting device 111 may employ a device capable of emitting monochromatic light (light having a specific range of wavelengths, for example, blue light) or white light (for example, mixed light of red light, green light, and blue light) in various directions when power is supplied. For example, the light-emitting device 111 may include an LED. The LED may be implemented in a variety of sizes and may include, for example, mini LEDs and/or micro LEDs.

The substrate 112 may fix the plurality of light-emitting devices 111 to prevent positions of the light-emitting devices 111 from being changed. In addition, the substrate 112 may supply power for enabling the light-emitting devices 111 to emit light to the individual light-emitting devices 111.

The substrate 112 may fix the plurality of light-emitting devices 111, and may include a synthetic resin and/or tempered glass and/or a printed circuit board (PCB) on which a conductive power feed line for supplying power to the light-emitting device 111 is formed.

The reflector sheet 120 may reflect light emitted from the plurality of light-emitting devices 111 in a forward direction or in a direction close to the forward direction.

A plurality of through holes 120a corresponding respectively to the plurality of light-emitting devices 111 of the light source module 110 are formed in the reflector sheet 120. In addition, the light-emitting devices 111 of the light source module 110 may pass through the through holes 120a and protrude forward of the reflector sheet 120.

For example, in an assembly process of the reflector sheet 120 and the light source module 110, the plurality of light-emitting devices 111 of the light source module 110 are inserted into the plurality of through holes 120a formed in the reflector sheet 120, As a result, the substrate 112 of the light source module 110 is located behind the reflector sheet 120, but the plurality of light-emitting devices 111 of the light source module 110 may be located in front of the reflector sheet 120.

Accordingly, the plurality of light-emitting devices 111 may emit light in front of the reflector sheet 120.

The plurality of light-emitting devices 111 may emit light in front of the reflector sheet 120 in various directions. Light may be emitted from the light-emitting device 111 not only toward the diffuser plate 130, but also toward the reflector sheet 120, and the reflector sheet 120 may reflect the light emitted toward the reflector sheet 120 toward the diffuser plate 130.

The light emitted from the light-emitting device 111 passes through various objects such as the diffuser plate 130 and the optical sheet 140. When the light passes the diffuser plate 130 and the optical sheet 140, a portion of the incident light is reflected from surfaces of the diffuser plate 130 and the optical sheet 140. The reflector sheet 120 may reflect the light reflected by the diffuser plate 130 and the optical sheet 140.

The diffuser plate 130 may be disposed in front of the light source module 110 and the reflector sheet 120, and may uniformly disperse the light emitted from the light-emitting device 111 of the light source module 110.

As described above, the plurality of light-emitting devices 111 are located at various positions on a rear surface of the backlight unit 100. Although the plurality of light-emitting devices 111 are equidistantly arranged on the rear surface of the backlight unit 100, non-uniformity of luminance may exist depending on the positions of the plurality of light-emitting devices 111.

To eliminate the non-uniformity of luminance due to the plurality of light-emitting devices 111, the diffuser plate 130 may diffuse the light emitted from the plurality of light-emitting devices 111 within the diffuser plate 130. In other words, the diffuser plate 130 may uniformly emit non-uniform light from the plurality of light-emitting devices 111 to the front surface.

The optical sheet 140 may include various sheets for improving luminance and luminance uniformity. For example, the optical sheet 140 may include a diffuser sheet 141, a first prism sheet 142, a second prism sheet 143, a reflective polarizing sheet 144, and the like.

The diffuser sheet 141 diffuses light for uniformity of luminance. The light emitted from the light-emitting device 111 is diffused by the diffuser plate 130, and may be diffused again by the diffuser sheet 141 included in the optical sheet 140.

The first prism sheet 142 and the second prism sheet 143 may concentrate the light diffused by the diffuser sheet 141, thereby increasing the luminance. The first prism sheet 142 and the second prism sheet 143 include a prism pattern of a triangular prism shape, and a plurality of these prism patterns are arranged adjacent to each other to form a plurality of bands.

The reflective polarizing sheet 144 is a kind of polarizing film, and may transmit a portion of the incident light, and reflect other portions to improve luminance. For example, the reflective polarizing sheet 144 may transmit light polarized in the same direction as a predetermined polarization direction of the reflective polarizing sheet 144 and reflect light polarized in a different direction from the polarization direction of the reflective polarizing sheet 144. In addition, the light reflected by the reflective polarizing sheet 144 is reused within the backlight unit 100, and the luminance of the display apparatus 10 may be improved by such light recycle.

The optical sheet 140 is not limited to the sheets or films shown in FIG. 4, and may further include more various sheets or films such as protective sheets.

The backlight unit 100 includes the plurality of light-emitting devices (light sources) 111, and may output surface light by diffusing the light emitted from the plurality of light sources 111. The liquid crystal panel 20 includes a plurality of pixels, and may control the plurality of pixels to allow each of the plurality of pixels to transmit or block light. An image may be formed by light passing through each of the plurality of pixels.

In this instance, the display apparatus 10 may perform local dimming to vary a brightness of light for each region of the backlight unit 100 in association with the output image to improve power consumption while increasing a contrast ratio.

For example, the display apparatus 10 may reduce the brightness of light of the light-emitting device 111 of the backlight unit 100 corresponding to a dark portion of an image to make the dark portion of the image darker, and may increase the brightness of light of the light-emitting device 111 of the backlight unit 100 corresponding to a bright portion of the image to make the bright portion of the image brighter. As a result, a contrast ratio or a brightness ratio of the image may be improved.

The display apparatus 10 may divide the backlight unit 100 into a plurality of blocks, and adjust current independently for each block according to an input image. Image transmission of the display apparatus 10 is performed through a method of frame-by-frame local dimming drives, and the driving of the current is adjusted according to the number of divided blocks of the light-emitting devices 111 in the backlight unit 100.

As a result, the display apparatus 10 may effectively improve a contrast ratio by lowering a supply current to the dimming blocks of regions where the input image is dark and increasing the supply current to the dimming blocks of regions where the input image is bright.

For local dimming, the plurality of light-emitting devices 111 included in the backlight unit 100 may be divided into a plurality of dimming blocks 200. For example, the plurality of dimming blocks 200 may be provided as a total of 60 blocks, composed of five rows and twelve columns, as shown in FIG. 5. As another example, the plurality of dimming blocks 200 may be provided as a total of 20 blocks, composed of five rows and four columns. However, the number of dimming blocks 200 is not limited to the above examples.

Referring to FIG. 5, each of the plurality of dimming blocks 200 may include at least one light-emitting device 111. The backlight unit 100 may supply the same driving current to the light-emitting devices 111 belonging to the same dimming block 200, and the light-emitting devices 111 belonging to the same dimming block 200 may emit light of the same brightness.

In addition, the backlight unit 100 may supply different driving currents to the light-emitting devices 111 belonging to different dimming blocks 200 according to dimming data, and the light-emitting devices 111 belonging to different dimming blocks 200 may emit light of different brightness.

As will be described below, among the light-emitting devices 111 belonging to the same dimming block 200, different driving currents may be supplied to light-emitting diodes (LEDs) that output light of different colors, and the same driving current may be supplied to LEDs that output light of the same color. To this end, dimming data corresponding to one dimming block may include RGB color values.

For example, each of the plurality of dimming blocks 200 may include N*M light sources arranged in an N*M matrix form (N and M are natural numbers). The N*M matrix refers to a matrix with N rows and M columns.

Because each of the light-emitting devices 111 includes an LED, each of the plurality of dimming blocks 200 may include N*M LEDs. That is, each of the plurality of dimming blocks 200 may include a predetermined number of light-emitting devices 111.

The plurality of dimming blocks 200 may be arranged on the substrate 112. That is, N*M LEDs may be disposed on the substrate 112.

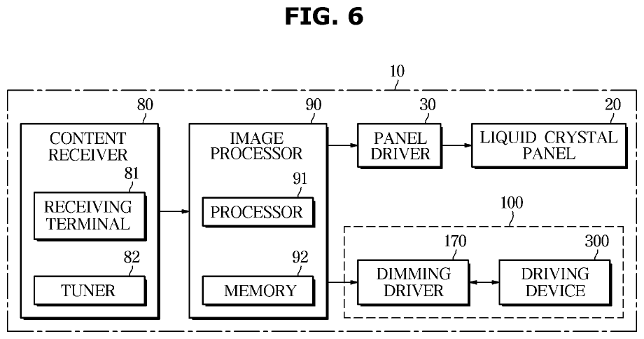

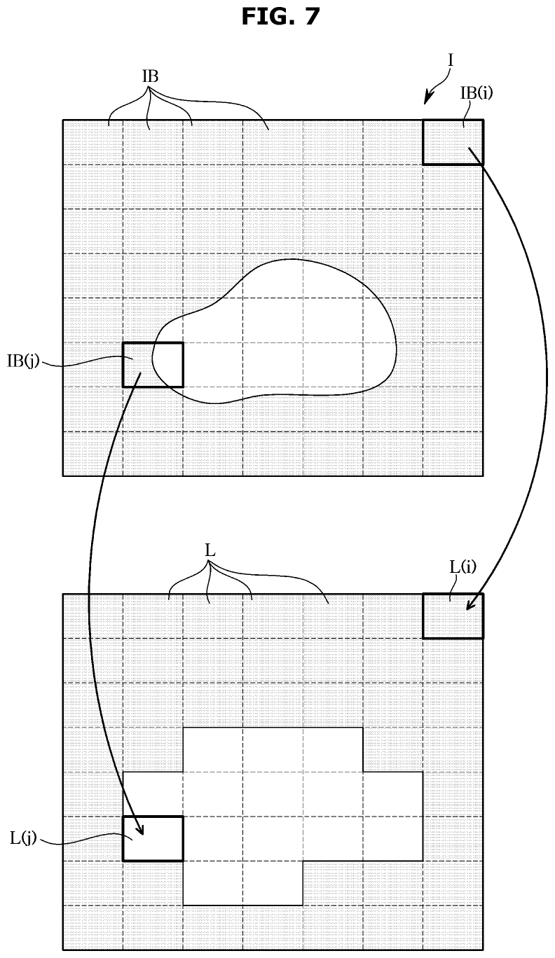

FIG. 6 is a control block diagram of a display apparatus according to an embodiment, and FIG. 7 illustrates an example in which a display apparatus converts image data into dimming data according to an embodiment.

Referring to FIG. 6, the display apparatus 10 may include a content receiver 80, an image processor 90, the panel driver 30, the liquid crystal panel 20, and the backlight unit 100. In this instance, the backlight unit 100 may include a dimming driver 170 that performs local dimming and a driving device 300 that drives the light-emitting device 111. The driving device 300 may be disposed on an upper surface or a lower surface of the substrate 112.

The content receiver 80 may include a receiving terminal 81 receiving content including a video signal and/or audio signal from content sources, and a tuner 82.

The receiving terminal 81 may receive a video signal and audio signal from content sources through a cable. For example, the receiving terminal 81 may include a component (YPbPr/RGB) terminal, a composite video blanking and sync (CVBS) terminal, an audio terminal, a high definition multimedia interface (HDMI) terminal, a universal serial bus (USB) terminal, and the like.

The tuner 82 may receive a broadcast signal from a broadcast reception antenna or a wired cable, and may extract a broadcast signal of a channel selected by a user from among broadcast signals. For example, the tuner 82 may pass a broadcast signal having a frequency corresponding to the channel selected by the user among a plurality of broadcast signals received through the broadcast reception antenna or wired cable, and may block a broadcast signal having a different frequency.

As described above, the content receiver 80 may receive an image including a video signal and an audio signal from the content sources through the receiving terminal 81 and/or the tuner 82, and may output the input image received through the receiving terminal 81 and/or the tuner 82 to the image processor 90.

The image processor 90 may include at least one processor 91 that processes an input image (image data) and a memory 92 that records/stores data.

The memory 92 stores programs and data for processing a video signal and/or an audio signal, and may temporarily remember data generated while processing the video signal and/or audio signal.

The memory 92 may include a non-volatile memory, such as read only memory (ROM) and flash memory, and a volatile memory, such as static random access memory (S-RAM) and dynamic random access memory (D-RAM).

The at least one processor 91 may receive an input image including a video signal and/or an audio signal from the content receiver 80, may decode the video signal into image data, and may generate dimming data from the image data. The image data and the dimming data may be output to the panel driver 30 and the dimming driver 170, respectively.

The at least one processor 91 may provide dimming data for local dimming to the backlight unit 100. The dimming data may include information about a luminance of each of the plurality of dimming blocks 200. For example, the dimming data may include information about an intensity of light output by the light-emitting devices 111 included in each of the plurality of dimming blocks 200. That is, the dimming data may include information about a magnitude of current supplied to the light-emitting devices 111 included in each of the plurality of dimming blocks 200.

The dimming data may include information about the magnitude of current supplied to each of the red LED 190R, the green LED 190G, and the blue LED 190B included in the light-emitting device 111 included in each of the plurality of dimming blocks 200.

The at least one processor 91 may calculate an average of RGB color values of each of the plurality of dimming blocks 200 based on the image data, and may generate dimming data of each of the plurality of dimming blocks 200 based on the average of the RGB color values.

The at least one processor 91 may obtain the dimming data from the image data decoded from the video signal.

The processor 91 may convert the image data into the dimming data in various manners. For example, as shown in FIG. 7, the processor 91 may divide an image I based on the image data into a plurality of image blocks IB. The number of the plurality of image blocks IB is equal to the number of the plurality of dimming blocks 200, and the plurality of image blocks IB may each correspond to the plurality of dimming blocks 200.

The processor 91 may obtain luminance values L of the plurality of dimming blocks 200 from the image data of the plurality of image blocks IB. The luminance values L of the plurality of dimming blocks 200 may include RGB color values of the plurality of dimming blocks 200.

The processor 91 may generate the dimming data by combining the luminance values L of the plurality of dimming blocks 200.

For example, the processor 91 may obtain a luminance value L of each of the plurality of dimming blocks 200 based on a maximum value among luminance values of pixels included in each of the image blocks IB.

A single image block includes a plurality of pixels P, and image data of a single image block may include image data of a plurality of pixels P (e.g., red data, green data, blue data, etc.). The processor 91 may calculate the luminance value of each of the pixels based on the image data of each of the pixels.

The image data may include a red data value corresponding to the red data, a green data value corresponding to the green data, and a blue data value corresponding to the blue data. Each of the red data value, the green data value, and the blue data value may indicate a luminance value within a predetermined range (e.g., 0 to 255).

The processor 91 may determine a maximum value of the luminance values of pixels included in an image block as a luminance value of a dimming block corresponding to the image block. For example, the processor 91 may determine a maximum value of luminance values of pixels included in the i-th image block IB(i) as a luminance value L(i) of an i-th dimming block, and may determine a maximum value of luminance values of pixels included in a j-th image block IB(j) as a luminance value L(j) of a j-th dimming block.

The processor 91 may generate the dimming data by combining the luminance values of the plurality of dimming blocks 200.

As such, the image processor 90 may decode the video signal obtained by the content receiver 80 into image data, and may generate the dimming data from the image data. In addition, the image processor 90 may transmit the image data and the dimming data to the liquid crystal panel 20 and the light source apparatus 100, respectively.

The liquid crystal panel 20 includes a plurality of pixels P capable of transmitting or blocking light, and the plurality of pixels P are arranged in a matrix form. In other words, the plurality of pixels P may be arranged in a plurality of rows and a plurality of columns.

As described above, each of the plurality of pixels P may include a red sub-pixel PR, a green sub-pixel PG, a blue sub-pixel PB, and a transparent sub-pixel PT.

The panel driver 30 may receive the image data from the image processor 90 and drive the liquid crystal panel 20 according to the image data. In other words, the panel driver 30 may convert image data, which is a digital signal (hereinafter, referred to as ‘digital image data’), into an analog image signal, which is an analog voltage signal, and may provide the converted analog image signal to the liquid crystal panel 20. Optical properties (e.g., light transmittance) of the plurality of pixels included in the liquid crystal panel 20 may change according to the analog image signal.

Driving the liquid crystal panel 20 according to the image data may include controlling an opening degree of each of the red sub-pixel PR, the green sub-pixel PG, the blue sub-pixel PB, and the transparent sub-pixel PT according to the image data.

Controlling the opening degree of each of the red sub-pixel PR, the green sub-pixel PG, the blue sub-pixel PB, and the transparent sub-pixel PT may include controlling an opening degree of each of the first liquid crystal cell 25R, the second liquid crystal cell 25G, the third liquid crystal cell 25B, and the fourth liquid crystal cell 25T.

The panel driver 30 may include, for example, a timing controller, a data driver, a scan driver, and the like.

The timing controller may receive image data from the image processor 90 and output the image data and a drive control signal to the data driver and the scan driver. The drive control signal may include a scan control signal and a data control signal, and the scan control signal and the data control signal may be used to control operations of the scan driver and the data driver, respectively.

The scan driver may receive a scan control signal from the timing controller, and may input-activate any one of the plurality of rows in the liquid crystal panel 20 according to the scan control signal. In other words, the scan driver may convert pixels, included in a single row among the plurality of pixels arranged in the plurality of rows and the plurality of columns, into a state capable of receiving an analog image signal. In this instance, the other pixels input-deactivated, except for the pixels input-activated by the scan driver, may not receive an analog image signal.

The data driver may receive image data and a data control signal from the timing controller and output the image data to the liquid crystal panel 20 according to the data control signal. For example, the data driver may receive the digital image data from the timing controller and convert the digital image data into an analog image signal. In addition, the data driver may provide the analog image signal to pixels included in any one row input-activated by the scan driver. In this instance, the pixels input-activated by the scan driver receive the analog image signal, and optical properties (e.g., light transmittance) of the input-activated pixels may change according to the received analog image signal.

As described above, the panel driver 30 may drive the liquid crystal panel 20 according to image data. As a result, an image corresponding to the image data may be displayed on the liquid crystal panel 20.

The light source apparatus 100 includes a plurality of light sources 111 that emit light, and the plurality of light sources 111 are arranged in a matrix form. In other words, the plurality of light sources 111 may be arranged in a plurality of rows and a plurality of columns. In addition, the light source apparatus 100 may be divided into a plurality of dimming blocks 200, and each of the plurality of dimming blocks 200 may include at least one light source.

The dimming driver 170 may receive dimming data from the image processor 90 and drive the light source apparatus 100 according to the dimming data. Here, the dimming data may include information about a luminance of each of the plurality of dimming blocks 200 or information about a brightness of the light sources included in each of the plurality of dimming blocks 200.

The dimming driver 170 may convert the dimming data, which is a digital signal, into an analog dimming signal, which is an analog voltage signal, and may provide the analog dimming signal to the light source apparatus 100. According to the analog dimming signal, an intensity of light emitted by the light sources included in each of the plurality of dimming blocks 200 may change.

In particular, the dimming driver 170 may provide the analog dimming signal sequentially to the plurality of dimming blocks 200 by an active matrix method, instead of directly providing the analog dimming signal to all of the plurality of dimming blocks 200.

As described above, the plurality of dimming blocks 200 may be arranged in a matrix form in the light source apparatus 100. In other words, the plurality of dimming blocks 200 may be arranged in a plurality of rows and a plurality of columns in the light source apparatus 100.

The dimming driver 170 may provide the analog dimming signal sequentially to dimming blocks belonging to each of the plurality of rows or to dimming blocks belonging to each of the plurality of columns.

For example, the dimming driver 170 may input-activate dimming blocks belonging to any one row of the plurality of dimming blocks 200, and may provide the analog dimming signal to the input-activated dimming blocks. Thereafter, the dimming driver 170 may input-activate dimming blocks belonging to another row of the plurality of dimming blocks 200, and may provide the analog dimming signal to the input-activated dimming blocks.

The dimming driver 170 may receive dimming data from the image processor 90, and may drive the driving device 300 according to the dimming data.

The driving device 300 may be configured to control at least one of the plurality of dimming blocks 200. The driving device 300 may control the dimming block 200 based on a control signal received from the dimming driver 170.

The driving device 300 may be referred to as a driving IC or a pixel IC, and the like, in that the driving device 300 is an integrated circuit for driving at least one of the plurality of dimming blocks 200.

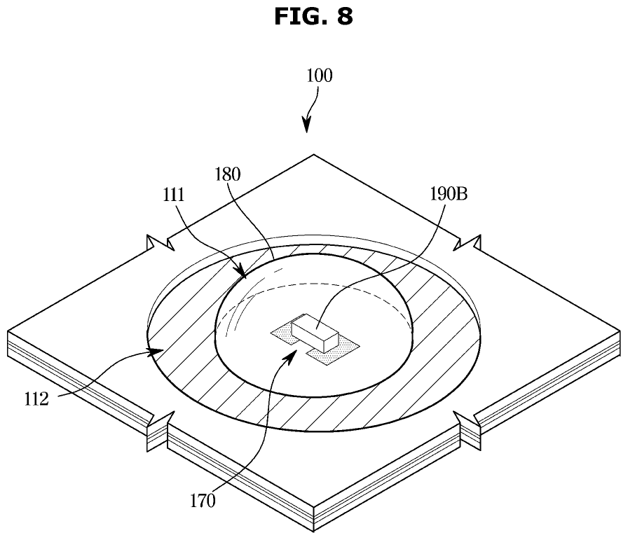

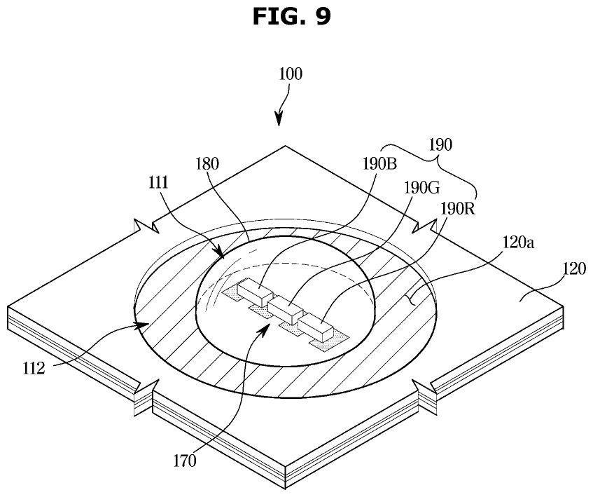

FIG. 8 illustrates an example of a light-emitting device included in a backlight unit according to an embodiment, and FIG. 9 illustrates another example of a light-emitting device included in a backlight unit according to an embodiment.

Referring to FIG. 8, the light-emitting device 111 may include the red LED 190R, the green LED 190G, and the blue LED 190B.

The LED (190R, 190G, and 190B; 190) may be a mini LED having a size of 500 μm×500 μm or less.

The red LED 190R may include at least one red LED connected in series to each other. The green LED 190G may include at least one green LED connected in series to each other. The blue LED 190B may include at least one blue LED connected in series to each other.

A plurality of LED groups 170 may be arranged in a two-dimensional matrix form on the upper surface of the substrate 112. That is, as shown in FIG. 4, as the plurality of light-emitting devices 111 are arranged in rows and columns, the plurality of LED groups 170 may be arranged in a two-dimensional matrix form.

In addition, according to embodiments, the plurality of light sources may be arranged such that three adjacent light sources form a substantially equilateral triangle. In this instance, a single light source may be disposed adjacent to six light sources. In addition, a distance between the single light source and each of the six adjacent light sources may be substantially the same.

However, the arrangement of the plurality of light-emitting devices 111 is not limited to the arrangement described above, and the plurality of light-emitting devices 111 may be disposed in various patterns to allow light to be emitted with uniform luminance.

The light-emitting device 111 may employ a device capable of emitting white light (light having a plurality of peak wavelengths, for example, mixed light of red light, green light, and blue light) in various directions when power is supplied.

That is, a single light-emitting device 111 may emit white light by including the red LED 190R, the green LED 190G, and the blue LED 190B.

An intensity of the red light emitted by the red LED 190R, an intensity of the green light emitted by the green LED 190G, and an intensity of the blue light emitted by the blue LED 190B may be independently changed based on the dimming data.

As shown in FIG. 8, each of the plurality of light-emitting devices 111 may include the LED 190 and an optical dome 180.

A thickness of the backlight unit 100 may also be reduced to reduce a thickness of the display apparatus 10. Each of the plurality of light-emitting devices 111 is thinned, and its structure is simplified in order to reduce the thickness of the backlight unit 100.

The LED 190 may include a P-type semiconductor and an N-type semiconductor for emitting light by recombination of holes and electrons. In addition, the LED 190 may be provided with a pair of electrodes for supplying holes and electrons to the P-type semiconductor and the N-type semiconductor, respectively.

The LED 190 may be configured to convert electrical energy into light energy. The LED 190 may emit light having a maximum intensity at a predetermined wavelength based on the supplied power. For example, the blue LED 190B may emit blue light having a peak value at a wavelength representing blue (e.g., a wavelength between 430 nm and 495 nm).

For example, a multilayer reflective structure in which a plurality of insulating films having different refractive indices are alternately stacked may be provided on the upper surface and/or the lower surface of the LED 190. For example, the multilayer reflective structure may be configured as a distributed Bragg reflector (DBR). The DBR is a structure in which two or more materials having different refractive indices are alternately stacked, and may refer to an optical element that provides high reflectance for light of a specific wavelength according to the principle of forming an optical path difference for each wavelength and inducing strong reflection in a specific frequency band.

In addition, the LED 190 may be directly attached to the substrate 112 by a chip on board (COB) method. For example, the light-emitting device 111 may include the LED 190 in which a LED chip or a LED die is directly attached to the substrate 112 without separate packaging.

The LED 190 may be manufactured as a flip-chip type. The LED 190 of the flip chip type may be formed by welding, upon attaching an LED being a semiconductor device to the substrate 112, an electrode pattern of a semiconductor device as it is to the substrate 112 without using a middle medium, such as a metal lead (wire) or a ball grid array (BGA). As such, by using neither a metal lead (wire) nor a ball grid array, the light-emitting device 111 including the LED 190 of the flip chip type may be miniaturized.

Although the flip-chip type LED 190 directly welded to the substrate 112 by the chip on board method has been described above, the light-emitting device 111 is not limited to the flip-chip type LED. For example, the light-emitting device 111 may include a package-type LED.

The optical dome 180 may cover the LED 19. For example, as shown in FIG. 8, the optical dome 180 may cover the blue LED 190B.

As another embodiment, as shown in FIG. 9, the optical dome 180 may cover a plurality of LEDs 190. That is, the optical dome 180 may cover the red LED 190R, the green LED 190G, and the blue LED 190B included in the LED group 170.

The optical dome 180 may refract and mix the red light, the green light, and the blue light emitted from the red LED 190R, the green LED 190G, and the blue LED 190B, respectively, thereby emitting white light.

Hereinafter, an arrangement of multi-channel jumpers with the improved pixel IC and LED wiring structure according to the present disclosure is described.

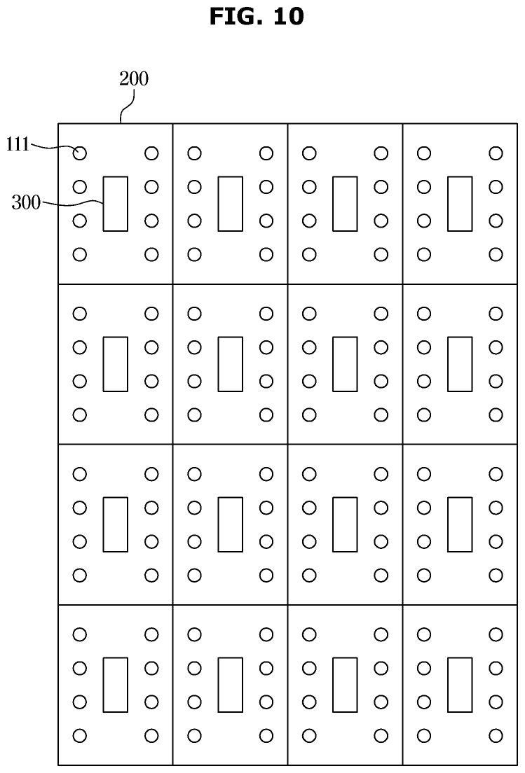

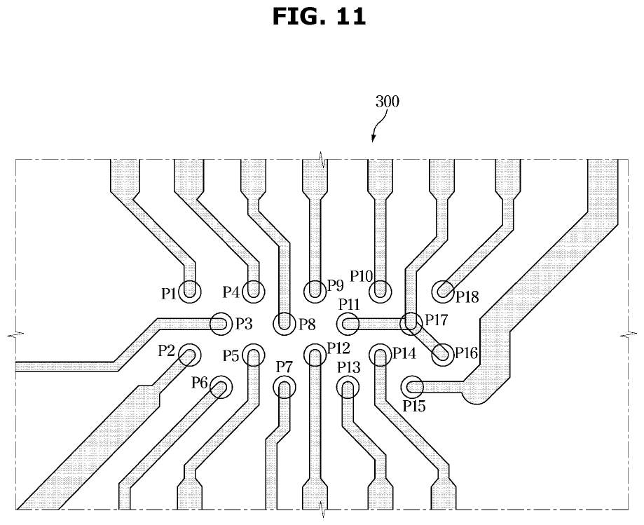

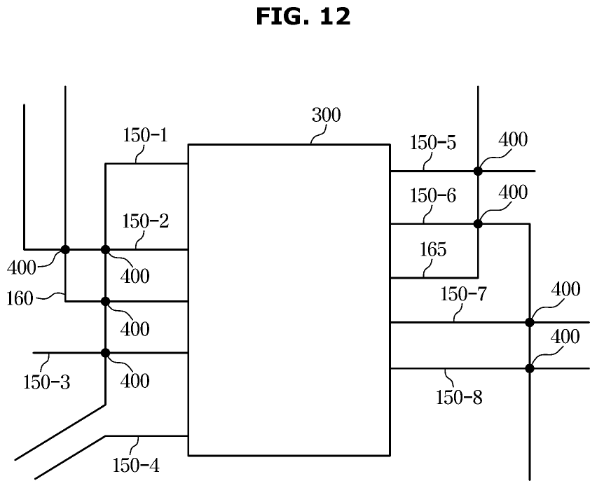

FIG. 10 is a diagram illustrating a structure of a pixel IC and LEDs according to an embodiment, FIG. 11 is a diagram illustrating a pin structure of a pixel IC according to an embodiment, and FIG. 12 is a diagram illustrating an existing structure of a pixel IC and wiring and an arrangement of jumper elements.

In the present disclosure, a substrate may include a single-sided metal printed circuit board (PCB). By using a single-sided PCB, the cost may be reduced compared to using a double-sided PCB.

A plurality of LEDs, a plurality of pixel ICs, and multi-channel jumpers to be described below may be arranged on the same surface of the substrate.

A single pixel IC may drive a defined number of LEDs. For example, each of the plurality of pixel ICs may drive eight LEDs. However, the number of LEDs is merely an example, and a single pixel IC may drive various numbers of LEDs.

Referring to FIG. 11, the pixel IC may include a plurality of pins P1 to P18 to which wiring for connection with a plurality of LEDs and other pixel ICs is connected. Various wirings extending from the plurality of pins may be connected to the plurality of LEDs and other pixel ICs.

Referring to FIG. 12, it may be seen that regions where various wirings 150, 160, and 165 extending from the pixel IC intersect with each other exist.

For example, intersection regions may occur between an LED line 150 connected to the LED for driving the LED, a scan line 160 for transmitting and receiving scan data between pixel ICs, and a power line 165 for transmitting and receiving power between pixel ICs.

To prevent physical contact between the wirings, jumper elements such as multi-channel jumpers may be used.

In existing technologies, physical contact between the wirings was prevented by using individual jumper elements at each intersection point (also referred to herein as a “convergence region”) where a plurality of LED lines 150-1, 150-2, 150-3, 150-4, 150-5, 150-6, 150-7, and 150-8, the scan line 160, the power line 165, and the like, extending from the pixel IC intersected. For example, as shown in FIG. 12, jumper elements were used in all regions where wirings intersected, such as the region where the first LED line 150-1 and the scan line 160 intersected, and the region where the first LED line 150-1 and the third LED line 150-3 intersected.

However, using the above method may increase the number of jumper elements, leading to an increase in cost.

According to the present disclosure, a structure that may minimize the number of jumper elements by changing the wiring structure and arranging the jumper elements around the pixel IC may be provided.

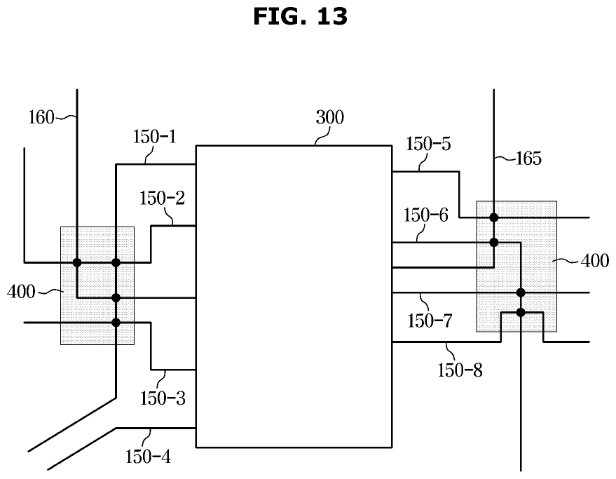

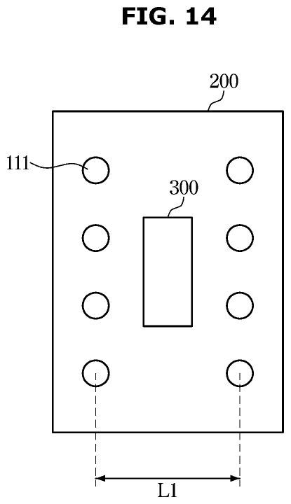

FIG. 13 is a diagram illustrating a structure of a pixel IC and wiring and an arrangement of multi-channel jumpers according to an embodiment, and FIG. 14 is a diagram illustrating a distance between a plurality of LEDs according to an embodiment.

Referring to the improved structure of FIG. 13, by partially changing the wiring structure of the plurality of LED lines for connecting the pixel IC 300 and each of the LEDs 111, the intersection regions between the wirings may be brought adjacent to one another.

For example, by changing the wiring structure of the second LED line 150-2 and the third LED line 150-3, the intersection regions of the wirings on the left side of the pixel IC 300 in the drawing may be brought adjacent to one another.

In addition, by using a multi-channel jumper 400 that may prevent physical contact of the plurality of wirings at once, physical contact at intersections of a plurality of wirings may be prevented. At the multi-channel jumper 400, at least three lines among the plurality of LED lines 150, the scan line 160, and the power line 165 may intersect.

The multi-channel jumper 400 may be arranged adjacent to the pixel IC 300. By changing the wiring structure, intersection regions may be formed adjacent to each other around the pixel IC 300, and by arranging the multi-channel jumper 400 at the intersection regions, the intersection between the wirings may be efficiently prevented.

For example, two multi-channel jumpers 400 may be provided as a pair on both sides of the pixel IC 300. One or more of the multi-channel jumpers 400 may be provided as a single, continuous, monolithic (i.e., integrally formed) structure. One or more of the multi-channel jumpers 400 may also be provided as a plurality of discrete, separable components that may be assembled together to form the multi-channel jumper 400. As shown in FIG. 13, at the multi-jumper element arranged on the left side of the pixel IC 300, the first to third LED lines 150-1, 150-2, and 150-3 and the scan line 160 may intersect (i.e., “overlap” or “converge”). Accordingly, physical contact among the first to third LED lines 150-1, 150-2, and 150-33 and the scan line 160 may be prevented. For example, this multi-channel jumper 400 may be configured to isolate each of the first to third LED lines 150-1, 150-2, and 150-33 and the scan line 160 from each other.

In addition, at the multi-jumper element arranged on the right side of the pixel IC 300, the fifth to eighth LED lines 150-5, 150-6, 150-7, and 150-8 and the power line 165 may intersect. Accordingly, physical contact among the fifth to eighth LED lines 150-5, 150-6, 150-7, and 150-8 and the power line 165 may be prevented.

However, the wiring structure, and the arrangement and the number of multi-channel jumpers 400 shown in FIG. 13 are merely an example, and may be implemented in various structures to reduce the number of multi-channel jumpers 400.

As described above, to minimize the number of multi-channel jumpers 400 and make the intersection regions between wirings closer to one another, the intersection regions and the multi-channel jumpers 400 may be located around the pixel IC 300.

For example, the multi-channel jumper 400 may be disposed within a defined distance from the pixel IC 300, and the defined distance may be a distance corresponding to twice a spacing L1 between the LEDs 111. However, the defined distance is merely an example, and may be determined as an appropriate distance to minimize the number of multi-channel jumpers 400. For example, the defined distance may be a distance corresponding to approximately 1.5 times the spacing L1 between the LEDs 111.

By changing the structure of wiring, such as the LED lines 150, the scan line 160, and the power line 165, and preventing the physical contact of adjacent intersection regions using the multi-channel jumper 400, the number of multi-channel jumpers 400 on a single-sided PCB may be minimized.

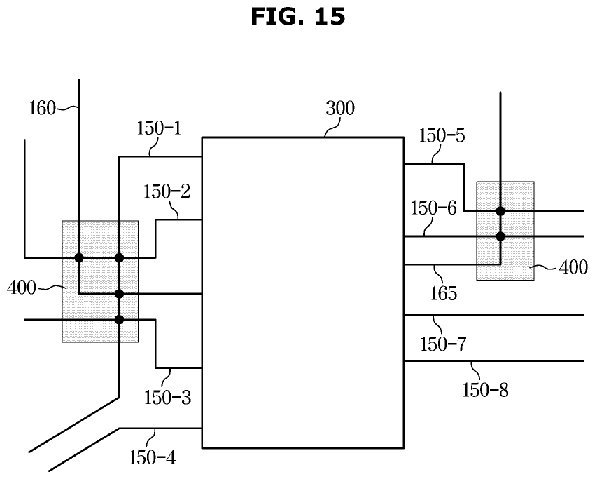

FIG. 15 is a diagram illustrating a structure of a pixel IC and wiring and an arrangement of multi-channel jumpers according to another embodiment.

Positions of pins of the pixel IC 300 and positions of the surrounding LEDs 111 are usually fixed in design. However, as another embodiment, intersection between wirings may be minimized by changing the position of the pins or the order of the LEDs 111.

For example, the number of intersection points may be minimized by adjusting the arrangement order of the LED lines 150-1 to 150-8. That is, the number of intersection points handled by a single multi-channel jumper 400 may be reduced, which allows the multi-channel jumper 400 to have a simpler structure.

FIG. 15 illustrates a structure in which the wiring order of the seventh LED line 150-7 and the eighth LED line 150-8 is changed. Accordingly, the existing intersection region of the seventh LED line 150-7 and the eighth LED line 150-8 may disappear, thereby preventing the intersection of the wirings. For example, the intersection regions of the other wirings may be arranged to be closer to one another, and thus the intersection of wirings may be more easily prevented.

However, the change in the wiring order of the seventh LED line 150-7 and the eighth LED line 150-8 shown in FIG. 15 is merely an example, and the wiring order and structure of lines may be changed to minimize the intersection region.

According to an embodiment of the present disclosure, a display apparatus may include: a substrate; a plurality of light-emitting diodes (LEDs) arranged on the substrate in a two-dimensional matrix; a plurality of pixel integrated circuits (ICs) each configured to drive a defined number of LEDs; a plurality of LED lines configured to connect the defined number of LEDs and the pixel IC; a scan line configured to transmit and receive scan data between the plurality of pixel ICs; a power line configured to transmit and receive power between the plurality of pixel ICs; and a plurality of multi-channel jumpers each installed at an intersection point of the plurality of LED lines, the scan line, and the power line to prevent physical contact between the lines, and wherein at least three lines among the plurality of LED lines, the scan line, and the power line may intersect at each of the plurality of multi-channel jumpers.

According to the present disclosure, the number of jumper elements may be reduced by rearranging a wiring structure on a single-sided PCB, thereby reducing cost.

In one or more embodiments, the first multi-channel jumper may be within a defined distance from the first pixel IC.

In one or more embodiments, the defined distance may be twice a spacing between adjacent ones of the LEDs.

In one or more embodiments, the substrate may include a single-sided metal printed circuit board (PCB); and the LEDs, the first pixel IC, and the first multi-channel jumper may be on a same surface of the substrate.

In one or more embodiments, the display apparatus may further include a second multi-channel jumper at a second convergence region, wherein another at least three lines among the one or more LED lines, the scan line, and the power line converge at the second convergence region; wherein the second multi-channel jumper is configured to isolate the another at least three lines from each other; wherein the first multi-channel jumper is at a first side of the first pixel IC, and the second multi-channel jumper is at a second side of the first pixel IC, wherein the at least three lines include two of the one or more LED lines and the scan line, and wherein the another at least three lines include another two of the one or more LED lines and the power line.

In one or more embodiments, the first pixel IC may be configured to drive eight or more of the LEDs.

In one or more embodiments, at least three lines among the one or more LED lines, the scan line, and the power line may converge at each of the multi-channel jumpers.

In one or more embodiments, each of the multi-channel jumpers may be within a defined distance from the first pixel IC.

In one or more embodiments, the multi-channel jumpers may include a first multi-channel jumper and a second multi-channel jumper, wherein at least three lines among the one or more LED lines and the scan line converge at the first multi-channel jumper at a first side of the first pixel IC, and wherein another at least three lines among the one or more LED lines and the power line converge at the second multi-channel jumper at a second side of the first pixel IC.

According to the present disclosure, the number of jumper elements may be reduced by rearranging a wiring structure on a single-sided PCB, thereby reducing cost.

Meanwhile, the disclosed embodiments may be implemented in the form of a recording medium that stores instructions executable by a computer. The instructions may be stored in the form of program codes, and when executed by a processor, the instructions may create a program module to perform operations of the disclosed embodiments. The recording medium may be implemented as a computer-readable recording medium.

The computer-readable recording medium may include all kinds of recording media storing instructions that can be interpreted by a computer. For example, the computer-readable recording medium may be read only memory (ROM), random access memory (RAM), a magnetic tape, a magnetic disc, a flash memory, an optical data storage device, etc.

Although embodiments of the present disclosure have been described with reference to the accompanying drawings, a person having ordinary skilled in the art will appreciate that other specific modifications may be easily made without departing from the technical spirit or essential features of the present disclosure. Therefore, the foregoing embodiments should be regarded as illustrative rather than limiting in all aspects.

1. A display apparatus, comprising:
a substrate;
light-emitting diodes (LEDs) on the substrate;
a first pixel integrated circuits (ICs) configured to drive one or more of the LEDs;
one or more LED lines configured to connect the one or more of the LEDs to the first pixel IC;
a scan line configured to transmit and receive scan data between the first pixel IC and one or more second pixel ICs;
a power line configured to transmit and receive power between the first pixel IC and the one or more second pixel ICs; and
a first multi-channel jumper at a first convergence region,
wherein at least three lines among the one or more LED lines, the scan line, and the power line converge at the first convergence region; and
wherein the first multi-channel jumper is configured to isolate the at least three lines from each other.

2. The display apparatus of claim 1, wherein the first multi-channel jumper is within a defined distance from the first pixel IC.

3. The display apparatus of claim 2, wherein the defined distance is twice a spacing between adjacent ones of the LEDs.

4. The display apparatus of claim 1, wherein the substrate comprises a single-sided metal printed circuit board (PCB), and
the LEDs, the first pixel IC, and the first multi-channel jumper are on a same surface of the substrate.

5. The display apparatus of claim 1, further comprising a second multi-channel jumper at a second convergence region,
wherein another at least three lines among the one or more LED lines, the scan line, and the power line converge at the second convergence region,
wherein the second multi-channel jumper is configured to isolate the another at least three lines from each other,
wherein the first multi-channel jumper is at a first side of the first pixel IC, and the second multi-channel jumper is at a second side of the first pixel IC,
wherein the at least three lines comprise two of the one or more LED lines and the scan line, and
wherein the another at least three lines comprise another two of the one or more LED lines and the power line.

6. The display apparatus of claim 1, wherein the first pixel ICs is configured to drive eight or more of the LEDs.

7. A display apparatus, comprising:
a substrate;
light-emitting diodes (LEDs) on the substrate;
a first pixel integrated circuit (IC) configured to drive one or more of the LEDs;
one or more LED lines configured to connect the one or more of the LEDs to the first pixel IC;
a scan line configured to transmit and receive scan data between the first pixel IC and a second pixel IC;
a power line configured to transmit and receive power between the first pixel IC and the second pixel IC; and
multi-channel jumpers respectively arranged adjacent to the first pixel IC at convergence regions, wherein the one or more LED lines, the scan line, and/or the power line converge at the convergence regions.

8. The display apparatus of claim 7, wherein at least three lines among the one or more LED lines, the scan line, and the power line converge at each of the multi-channel jumpers.

9. The display apparatus of claim 7, wherein each of the multi-channel jumpers is within a defined distance from the first pixel IC.

10. The display apparatus of claim 9, wherein the defined distance is twice a spacing between adjacent ones of the LEDs.

11. The display apparatus of claim 7, wherein the substrate comprises a single-sided metal printed circuit board (PCB), and
the LEDs, the first pixel IC, and the multi-channel jumpers are on a same surface of the substrate.

12. The display apparatus of claim 7, wherein the multi-channel jumpers comprise a first multi-channel jumper and a second multi-channel jumper,
wherein at least three lines among the one or more LED lines and the scan line converge at the first multi-channel jumper at a first side of the first pixel IC, and
wherein another at least three lines among the one or more LED lines and the power line converge at the second multi-channel jumper at a second side of the first pixel IC.

13. The display apparatus of claim 7, wherein the first pixel IC is configured to drive eight or more of the LEDs.
